(19) United States
(12) Patent Application Publication
(10) Pub. No.: US 2005/0206013 A1
(43) Pub. Date: Sep. 22, 2005

(54) Chip module

(76) Inventor: Hui Chiang Yang, Hsintien City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/839,392

(22) Filed: May 6, 2004

(30) Foreign Application Priority Data
Mar. 19, 2004 (TW) 93204253

(51) Int. Cl. H01L 23/34

(52) U.S. Cl. 257/782; 257/707; 257/784

(57) ABSTRACT

A chip module mounted on a circuit board has a chip mount pad, a chip, a number of leads, and an insulative element. The chip mount pad has a receiving portion and a supporting portion. The receiving portion defines a receiving surface and a heat dissipation surface opposite the receiving surface. The receiving surface faces the circuit board. The supporting portion extends from the receiving portion to the circuit board, and has a distal end fixed on the circuit board. The insulative element is fixed on the receiving surface of the receiving portion of the chip mount pad, and the heat dissipation surface is exposed. Therefore, the chip module of the present invention can be firmly mounted on the circuit board, and heat dissipation efficiency of the chip module is improved.

### BACKGROUND OF THE INVENTION

1. Field of the Invention

The present invention relates to a chip module, and more particularly, to a chip module that can be mounted firmly on a circuit board, whereby heat dissipation efficiency thereof is improved.

2. Background of the Invention

It is well known that electronic equipment has circuit boards therein, and electronic components are mounted on the circuit boards. A complete circuit is formed by means of a design of conductor patterns on a circuit board and electronic components are arranged and connected on the circuit board as well, so as to provide the functions of electronic equipment. Whether the functions of the electronic equipment run normally depends on whether the electronic components are connected reliably on the circuit board or not.

In addition, because operating efficiency and functions of an electronic component, such as a chip module, are gradually improved, high heat generated by the chip when it operates has to be transmitted out, so as to ensure a normal operation of the electronic equipment.

Referring to FIG. 1, a conventional chip module is mounted on a circuit board 9′. The chip module includes a chip mount pad 1′, a chip 2′, a number of leads 3, and an insulative element 5′. The chip mount pad 1′ defines a receiving surface 101′ and a heat dissipation surface 102′ opposite the receiving surface 101′. The chip 2′ is attached on the receiving surface 101′. Each of the leads 3′ has an interior end electrically connected to a bonding pad 20′ of the chip 2′ by a wire 4′. The insulative element 5′ encloses the chip 2′, the interior ends of the leads 3′, and the wires 4′. The insulative element 5′ is fixed on the receiving surface 101′ of the chip mount pad 1′, and the heat dissipation surface 102′ is exposed. The circuit board 9′ has a number of electric pads 90′ and a heat conductive member 92′. Each of the leads 3′ has an exterior end fixed on one of the electric pads 90′ of the circuit board 9′. The heat dissipation surface 102′ of the chip mount pad 1′ is fixed on the heat conductive member 92′ of the circuit board 9′.

The leads 3′ and the heat dissipation surface 102′ of the chip mount pad 1′ are respectively connected to the electric pads 90′ and the heat conductive member 92′ of the circuit board 9′, so that the chip module is mounted on the circuit board 9′. As the chip mount pad 1′ is disposed between the insulative element 5′ and the circuit board 9′, high heat generated by the chip 2′ is sealed in the insulative element 5′ and is transmitted upwardly with difficulty. The high heat of the chip 2′ is unable to contact air to dissipate, and can only be transmitted out via the heat conductive member 92′ of the circuit board 9′, which affects the heat dissipation efficiency thereof. If the heat conductive member 92′ is enlarged, the improvement of the heat dissipation efficiency is still limited, and more space on the circuit board 9′ is occupied. Moreover, if the chip mount pad 1′ is disposed above the chip 2′, the chip mount pad 1′ can be directly exposed in the air to dissipate heat, but the chip module is mounted on the circuit board only by leads 3. As a result, the chip module cannot be mounted firmly on the circuit board 9′.

Accordingly, as discussed above, the conventional chip module still has some drawbacks that could be improved. The present invention aims to resolve the drawbacks in the prior art.

### SUMMARY OF INVENTION

The primary object of the invention is therefore to specify a chip module, so that the chip module can be mounted firmly on a circuit board, and heat dissipation efficiency thereof is improved.

According to the invention, the object is achieved via a chip module mounted on a circuit board which has a number of electric pads, comprising a chip mount pad, a chip, a number of leads, and an insulative element. The chip mount pad includes a receiving portion and a supporting portion. The receiving portion defines a receiving surface and a heat dissipation surface opposite the receiving surface. The receiving surface faces the circuit board, and the supporting portion extends from the receiving portion to the circuit board and has a distal end fixed on the circuit board. The chip is attached on the receiving surface of the receiving portion of the chip mount pad. Each of the leads has an interior end disposed near the chip and an exterior end fixed on one of the electric pads of the circuit board. The insulative element encloses the chip and the interior ends of the leads. The insulative element is fixed on the receiving surface of the receiving portion of the chip mount pad, and the heat dissipation surface is exposed.

The supporting portion of the chip mount pad is fixed on the circuit board, so that the chip module of the present invention can be mounted firmly on the circuit board, and the heat dissipation surface of the receiving portion of the chip mount pad can dissipate heat directly to improve the heat dissipation efficiency thereof.

To provide a further understanding of the invention, the following detailed description illustrates embodiments and examples of the invention. Examples of the more important features of the invention thus have been summarized rather broadly in order that the detailed description thereof that follows may be better understood, and in order that the contributions to the art may be appreciated. There are, of course, additional features of the invention which will be described hereinafter and which will form the subject of the claims appended hereto.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a cross-sectional view of a chip module of the prior art;

FIG. 2 is a cross-sectional view of a chip module according to a first embodiment of the present invention;

FIG. 3 is a perspective schematic view of a chip module, which shows a manner of bonding wires according to a first embodiment of the present invention;

FIG. 4 is a perspective schematic view of a chip module, which shows another manner of bonding wires according to a first embodiment of the present invention;

FIG. 5 is a perspective schematic view of a chip module, which shows still another manner of bonding wires according to a first embodiment of the present invention;

FIG. 6 is a cross-sectional view of a chip module according to a second embodiment of the present invention; and

FIG. 7 is a cross-sectional view of a chip module plus a heat dissipation device according to a second embodiment of the present invention.

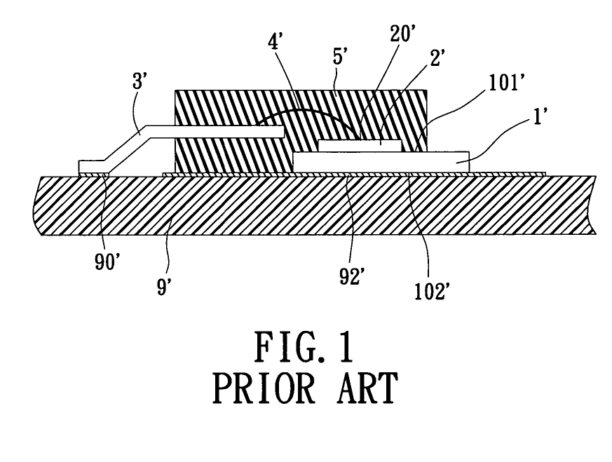

### DETAILED DESCRIPTION OF THE EMBODIMENTS

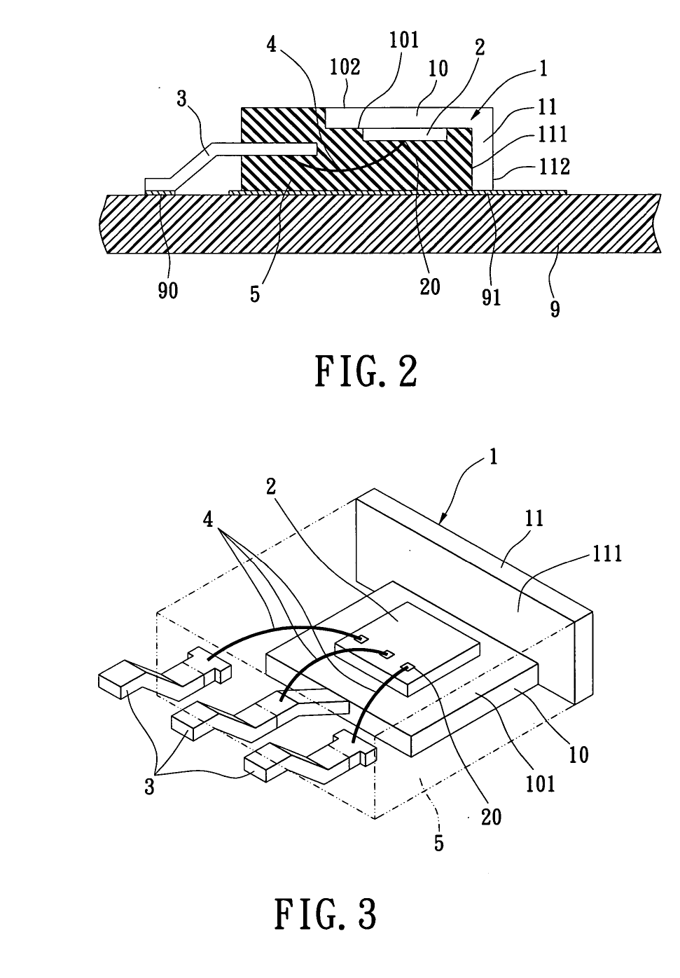

FIG. 2 and FIG. 3 illustrate a first embodiment of the present invention. The present invention provides a chip module. The chip module is mounted on a circuit board 9, which has a number of electric pads 90. The chip module comprises a chip mount pad 1, a chip 2, a number of leads 3, a number of wires 4, and an insulative element 5.

The chip mount pad 1 includes a receiving portion 10 and a supporting portion 11. The receiving portion 10 defines a receiving surface 101 and a heat dissipation surface 102 opposite the receiving surface 101. The receiving surface 101 faces the circuit board 9, and the supporting portion 11 extends from an edge of the receiving portion 10 to the circuit board 9 and has a distal end fixed on the circuit board 9 by, for example, adhesion. In this embodiment, the circuit board 9 has an electric conductive member 91 (such as a copper wire on a printed circuit board), and the distal end of the supporting portion 11 is fixed on the electric conductive member 91 by, for example, soldering or adhesion. The supporting portion 11 defines an inner surface 111 and an outer surface 112 opposite the inner surface 111.

The chip 2 is attached on the receiving surface 101 of the receiving portion 10 of the chip mount pad 1 by, for example, adhesion. The chip 2 has a number of bonding pads 20 thereon. The inner surface 111 of the supporting portion 11 of the chip mount pad 1 faces the chip 2.

Each of the leads 3 has an interior end disposed near the chip 2 and arranged at an edge of the receiving portion 10 of the chip mount pad 1 opposite the edge extending the supporting portion 11. Before the chip module of the present invention is complete, each of the leads 3 has an exterior end connecting to a guiding strip, and the interior end of one of the leads 3 connects to the receiving portion 10 of the chip mount pad 1, so as to form a lead frame. The lead frame is made of electric conductive and thermal conductive material. When the chip module of the present invention is complete and is disposed on the circuit board 9, the exterior ends of the leads 3 are fixed respectively on the electric pads 90 of the circuit board 9 by, for example, soldering or adhesion.

Each of the wires 4 has two ends electrically connecting one of the bonding pads 20 of the chip 2 and the interior end of one of the leads 3, respectively.

The insulative element 5 encloses the chip 2, the interior ends of the leads 3, and the wires 4. The insulative element 5 is fixed on the receiving surface 101 of the receiving portion 10 of the chip mount pad 1, and the heat dissipation surface 102 is exposed. In addition, the insulative element 5 is fixed on the inner surface 111 of the supporting portion 11, and the outer surface 111 is exposed.

Because the supporting portion 11 of the chip mount pad 1 is fixed on the circuit board 9, and the leads 3 are fixed respectively on the electric pads 90 of the circuit board 9, the chip module of the present invention can be firmly mounted on the circuit board 9 without being affected by exterior forces during fabrication or use of the chip module. As illustrated in the prior art, the electric conductive member 91 can also be a heat dissipation surface. The heat dissipation surface 102 of the receiving portion 10 of the chip mount pad 1 and the outer surface 112 of the supporting portion 11 are exposed to the air, so as to dissipate heat directly to improve heat dissipation efficiency. Therefore, the chip mount pad 1 has both a fixing function and a heat dissipation function, and can achieve two-sides heat dissipation.

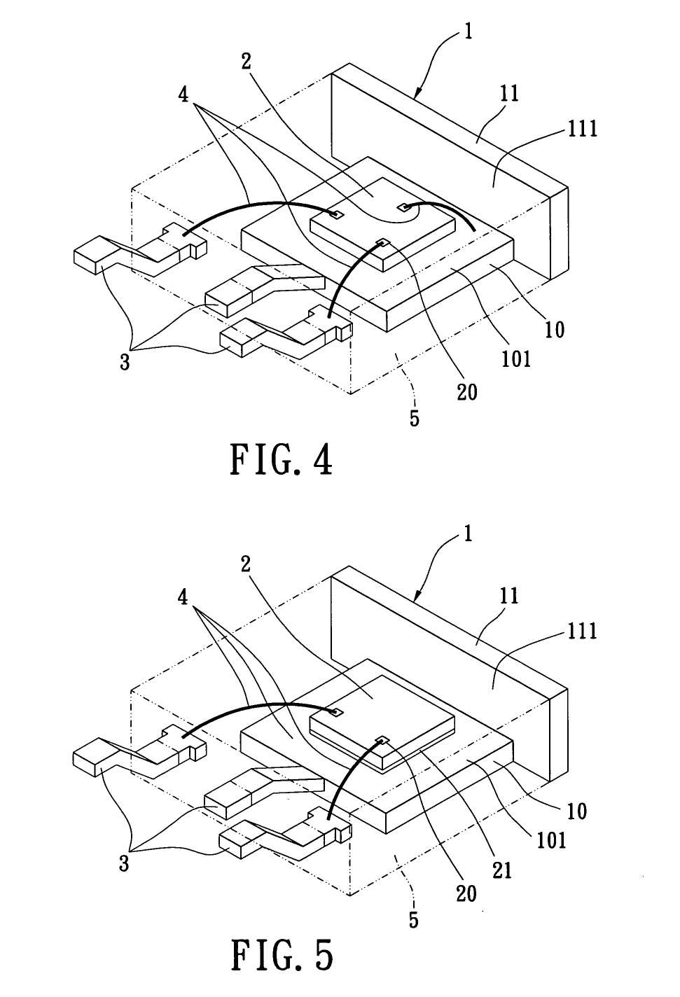

Reference is made to FIG. 4, which shows another manner of bonding wires. Each of part of the wires 4 has two ends respectively electrically connecting one of part of the bonding pads 20 of the chip 2 and the interior end of one of part of the leads 3, and each of another part of the wires 4 has two ends respectively electrically connecting one of another part of the bonding pads 20 of the chip 2 and the receiving surface 101 of the chip mount pad 1 without using the lead 3 connecting with the chip mount pad 1. Because the supporting portion 11 of the chip mount pad 1 is fixed on the electric conductive member 91 of the circuit board 9, the bonding pads 20 of the chip 2 can be electrically connected to the electric conductive member 91 of the circuit board 9 via the chip mount pad 1, so that the chip mount pad 1 has an electric conductive function.

Reference is made to FIG. 5, which shows still another manner of bonding wires. The chip 2 has a number of bonding pads 20 and an electric conductive surface 21, which electrically connects with the receiving surface 10 of he chip mount pad 1. Each of the wires 4 has two ends respectively electrically connecting one of the bonding pads 20 of the chip 2 and the interior end of one of the leads 3 without using the lead 3 connecting with the chip mount pad 1. Therefore, the electric conductive surface 21 of the chip 2 can be electrically connected with the electric conductive member 91 of the circuit board 9 via the chip mount pad 1, so as allow more flexibility in design of the circuit.

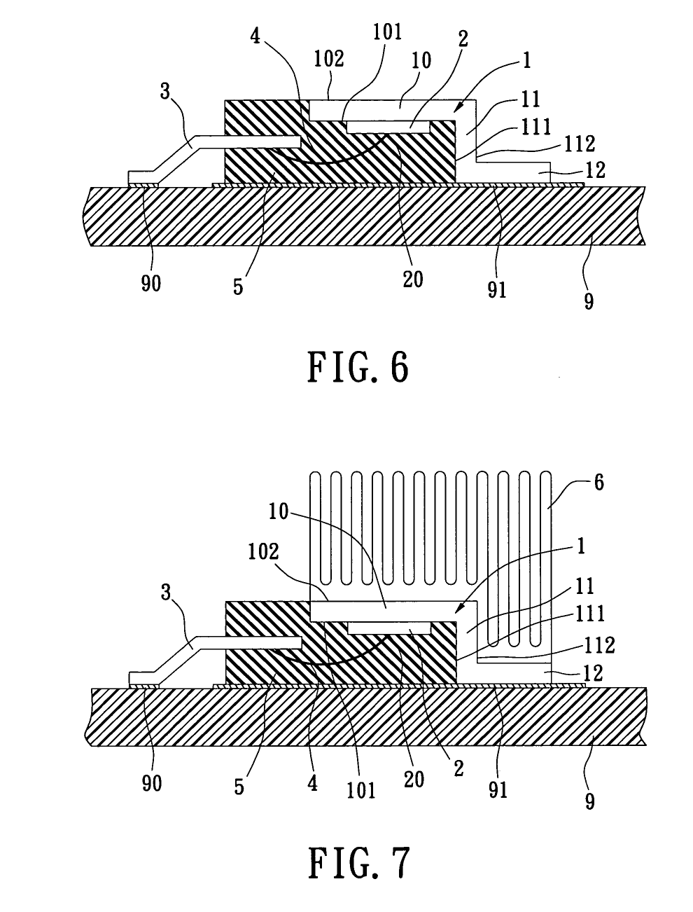

Reference is made to FIG. 6, which illustrates a second embodiment of the present invention. In this embodiment, the chip mount pad 1 further includes a resting portion 12 extending outwardly from the distal end of the supporting portion 11 and fixed on the circuit board 9. Therefore, the mounting of the chip module of the present invention is firm, and the heat dissipation area of the chip mount pad 1 is increased to further improve the heat dissipation efficiency thereof.

Referring to FIG. 7, a heat dissipation device 6 is mounted on the heat dissipation surface 102 of the receiving portion 10 of the chip mounted pad 1. Therefore, the heat dissipation efficiency thereof is much better.

As indicated above, the chip module of the present invention has the following advantages:

(1) The supporting portion of the chip mount pad is fixed on the circuit board, so that the chip module of the present invention can be mounted firmly on the circuit board, and the heat dissipation surface of the receiving portion of the chip mount pad and the supporting portion are exposed to the air to dissipate heat directly and improve the heat dissipation efficiency. Therefore, the chip mount pad has both a fixing function and a heat dissipation function.

(2) The supporting portion of the chip mount pad is fixed on the electric conductive member of the circuit board, so that the chip can be electrically connected to the circuit board via the chip mount pad. Therefore, the chip mount pad has an electric conductive function.

(3) The chip mount pad further has a resting portion fixed on the circuit board, so that the chip module of the present invention is mounted more firmly on the circuit board, and the heat dissipation area is increased to further improve the heat dissipation efficiency thereof.

It should be apparent to those skilled in the art that the above description is only illustrative of specific embodiments and examples of the invention. The invention should therefore cover various modifications and variations made to the herein-described structure and operations of the invention, provided they fall within the scope of the invention as defined in the following appended claims.

1. A chip module mounted on a circuit board having a number of electric pads, comprising:
a chip mount pad including a receiving portion and a supporting portion, the receiving portion defining a receiving surface and a heat dissipation surface opposite the receiving surface, the receiving surface facing the circuit board, and the supporting portion extending from the receiving portion to the circuit board and having a distal end fixed on the circuit board;
a chip attached on the receiving surface of the receiving portion of the chip mount pad;
a number of leads, each of the leads having an interior end disposed near the chip and an exterior end fixed on one of the electric pads of the circuit board; and
an insulative element enclosing the chip and the interior ends of the leads, the insulative element being fixed on the receiving surface of the receiving portion of the chip mount pad, and the heat dissipation surface being exposed.

2. The chip module as claimed in claim 1, wherein the chip has a number of bonding pads, the chip module has a number of wires, and each of the wires has two ends electrically connecting one of the bonding pads of the chip and the interior end of one of the leads, respectively.

3. The chip module as claimed in claim 1, wherein the chip has a number of bonding pads, the chip module has a number of wires, and the circuit board has an electric conductive member, wherein the distal end of the supporting portion of the chip mount pad is fixed on the electric conductive member, wherein each of part of the wires has two ends respectively electrically connecting one of part of the bonding pads of the chip and the interior end of one of part of the leads, and each of another part of the wires has two ends respectively electrically connecting one of another part of the bonding pads of the chip and the receiving surface of the chip mount pad.

4. The chip module as claimed in claim 1, wherein the chip has a number of bonding pads and an electric conductive surface electrically connecting with the receiving surface of the chip mount pad, the chip module has a number of wires, and the circuit board has an electric conductive member, wherein the distal end of the supporting portion of the chip mount pad is fixed on the electric conductive member, and wherein each of the wires has two ends respectively electrically connecting one of the bonding pads of the chip and the interior end of one of the leads.

5. The chip module as claimed in claim 1, wherein the supporting portion of the chip mount pad defines an inner surface and an outer surface opposite the inner surface, the insulative element is fixed on the inner surface, and the outer surface is exposed, and wherein the chip mount pad further includes a resting portion extending outwardly from the distal end of the supporting portion and being fixed on the circuit board.

6. The chip module as claimed in claim 1, wherein a heat dissipation device is mounted on the heat dissipation surface of the chip mount pad.
